(19) United States
(12) Patent Application Publication
(10) Pub. No.: US 2026/0293266 A1
(43) Pub. Date: Sep. 24, 2026

(54) DOUBLE-GATE MOS TRANSISTOR AND MANUFACTURING METHOD

(71) Applicant: STMicroelectronics International N.V., Geneva (CH)

(72) Inventors: Brice Arrazat, Belcodene (FR); Christian Rivero, Peynier (FR); Jordan Innocenti, La Ciotat (FR)

(21) Appl. No.: 19/570,051

(22) Filed: Mar. 17, 2026

(30) Foreign Application Priority Data
Mar. 19, 2025 (FR) 2502815

(51) Int. Cl. H10D 64/27; H10D 30/01; H10D 30/60

(52) U.S. Cl. CPC H10D 64/518; H10D 30/022; H10D 30/605

(57) ABSTRACT

An embodiment transistor includes a semiconductor substrate extending along a plane with an active area of the substrate along a first direction of the plane. The transistor includes a gate structure having a first region insulated from and located at least partly above the active area, and a second region insulated from and located above the first region. The first region has a first length in the first direction, and the second region has a second length in the first direction that is greater than the first length. The second region further extends on either side of the first region in the first direction. Along a second direction of the plane perpendicular to the first direction, the second region has a first longitudinal edge that reaches or extends beyond a second longitudinal edge of the first region. The second region has an opening that extends in the second direction from a third longitudinal edge of the second region opposite to the first longitudinal edge.

### CROSS-REFERENCE TO RELATED APPLICATIONS

This application claims the priority benefit of French patent application number FR2502815, filed on Mar. 19, 2025, entitled “Transistors MOS à double grille et procédé de fabrication” which is hereby incorporated by reference to the maximum extent allowable by law.

### TECHNICAL FIELD

The present disclosure generally concerns electronic circuits, and in particular MOS transistors. The present disclosure concerns in particular MOS transistors with a double gate region, or double gate.

### BACKGROUND

Metal oxide semiconductor field effect transistors, or MOSFETs, are transistors comprising a conductive gate region electrically insulated from a semiconductor substrate, generally made of silicon, or from a well formed in a semiconductor substrate, by a dielectric layer called gate oxide or gate insulator, the gate region topping an active area comprising a source region, a drain region, and a channel-forming region between the source region and the drain region. A MOSFET may be referred to as a MOS transistor, for short.

N-channel MOS transistors, or NMOS transistors, designate transistors having N-type doped source and drain regions, for example doped with arsenic or phosphorus atoms. P-channel MOS transistors, or PMOS transistors, are transistors having P-type doped source and drain regions, for example, doped with boron or indium atoms.

The present disclosure particularly concerns MOS transistors with a double gate region, that is, MOS transistors having their gate structure comprising a first gate region topped by a second gate region, with, generally, an insulating layer between these two gate regions.

MOS transistors with a double gate region can be configured in particular to form MOS transistors capable of holding a medium voltage (medium-voltage transistors, or MV MOS transistors), for example between 10 and 13 volts, between the drain and the semiconductor substrate, or even MOS transistors capable of holding a high voltage (high-voltage transistors, or HV MOS transistors) between the drain and the semiconductor substrate, for example greater than 14 volts, in particular enabling to increase the implantation distance between the source and the channel and between the drain and the channel, and enabling to increase the breakdown voltage (BV).

Transistors with a double gate region can, for example, be used in non-volatile memory cells. A non-volatile memory cell, for example of electrically erasable and programmable type, known by the acronym EEPROM, for electrically-erasable programmable read-only memory, comprises a state transistor with a double gate region, generally a control gate region topped by a floating gate region. The state transistor can be selectable via a selection transistor series-connected with the state transistor. For reasons of simplification of the memory cell manufacturing method, it is easier to manufacture a selection transistor comprising a transistor with a double gate region having its two gate regions preferably connected to each other so as to form a single gate.

In general, a medium-voltage or high-voltage MOS transistor has a planar structure, costly in terms of surface footprint. In particular, a high-voltage MOS transistor can have a planar structure with an extended drain, called “drift MOS,” so as to have a high breakdown voltage (BV). However, a drift MOS transistor is very costly in terms of surface footprint.

### SUMMARY

In an embodiment, a MOSFET transistor includes a semiconductor substrate extending along a plane with a drain region and a source region located in an active area of the semiconductor substrate along a first direction of the plane. The transistor includes a gate structure having a first region insulated from and located at least partly above the active area, and a second region insulated from and located above the first region. The first region has a first length in the first direction, and the second region has a second length in the first direction that is greater than the first length. The second region further extends on either side of the first region in the first direction. Along a second direction of the plane perpendicular to the first direction, the second region has a first longitudinal edge that reaches or extends beyond a second longitudinal edge of the first region. The second region has an opening that extends in the second direction from a third longitudinal edge of the second region opposite to the first longitudinal edge.

An embodiment method of manufacturing a MOSFET transistor involves forming a first region of a gate structure that is insulated from and above an active area of a semiconductor substrate extending along a plane, where the first region has a first length in a first direction of the plane. The method includes forming a second region of the gate structure that is insulated from and above the first region, where the second region has a second length in the first direction greater than the first length and further extends on either side of the first region in the first direction. The second region is formed so that a first longitudinal edge of the second region reaches or extends beyond a second longitudinal edge of the first region along a second direction of the plane perpendicular to the first direction. Forming the second region includes forming an opening in the second direction from a third longitudinal edge of the second region opposite to the first longitudinal edge. The method further includes forming a drain region and a source region on either side of the second region in the first direction.

An embodiment electronic circuit includes a semiconductor substrate extending along a plane and at least one MOSFET transistor. The MOSFET transistor includes a drain region and a source region located in an active area of the semiconductor substrate along a first direction of the plane, and a gate structure having a first region insulated from and located at least partly above the active area and a second region insulated from and located above the first region. The first region has a first length in the first direction, and the second region has a second length in the first direction greater than the first length. The second region further extends on either side of the first region in the first direction. Along a second direction of the plane perpendicular to the first direction, the second region has a first longitudinal edge that reaches or extends beyond a second longitudinal edge of the first region. The second region has an opening that extends in the second direction from a third longitudinal edge of the second region opposite to the first longitudinal edge.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A shows, in a simplified and partial top view, of an example of a MOS transistor;

FIG. 1B shows, in a simplified and partial top view, another example of a MOS transistor;

FIG. 2A shows, in a simplified and partial top view, a MOS transistor according to an embodiment;

FIG. 2B shows, in a simplified and partial top view, a MOS transistor according to an alternative embodiment of the MOS transistor of FIG. 2A;

FIG. 2C shows, in a simplified and partial top view, a MOS transistor according to another alternative embodiment of the MOS transistor of FIG. 2A;

FIG. 3A shows, in a simplified and partial top view, a MOS transistor according to another embodiment;

FIG. 3B shows, in a simplified and partial top view, a MOS transistor according to an alternative embodiment of the MOS transistor of FIG. 3A;

FIG. 3C shows, in a simplified and partial top view, a MOS transistor according to an alternative embodiment of the MOS transistor of FIG. 3B; and

FIG. 4A, FIG. 4B, FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, and FIG. 11B are three-dimensional longitudinal cross-section views, partially and schematically illustrating successive steps of a method of manufacturing a MOS transistor according to an embodiment.

### DESCRIPTION OF EMBODIMENTS

There exists a need to decrease the surface footprint of a MOS transistor while offering an electrical performance equivalent to or better than that of a known MOS transistor, in particular for an MV MOS or HV MOS transistor.

An embodiment overcomes all or part of the disadvantages of known MOS transistors.

An embodiment provides a MOSFET transistor located inside and on top of a semiconductor substrate extending along a plane, the MOSFET transistor comprising: a drain region and a source region located in an active area of the semiconductor substrate along a first direction of the plane; and a gate structure comprising a first region insulated from, and located at least partly above, the active area, and a second region insulated from, and located above, the first region; the first region having a first length, the second region having a second length greater than the first length, and the second region further extending on either side of the first region in the first direction; the second region having a first longitudinal edge which reaches the limit of, or which extends beyond, a second longitudinal edge of the first region, in a second direction of the plane perpendicular to the first direction; the second region having an opening which extends in the second direction from a third longitudinal edge of said second region opposite to the first longitudinal edge.

According to an embodiment, the first region of the gate structure is positioned on a gate insulator layer and is overlaid by an inter-gate insulator layer, and the second region of the gate structure is positioned astride, at least in the first direction, the first region overlaid by the inter-gate insulator layer and the gate insulator layer.

According to an embodiment, the first region is located on both sides of the active area in the second direction.

According to an embodiment, the second region is located on both sides of the active area in the second direction.

According to an embodiment, the active area has a third length greater than the second length, and a third width smaller than a first width of the first region and than a second width of the second region.

According to an embodiment, the opening of the second region is a notch which stops before the first longitudinal edge.

According to an embodiment, the opening is a notch that stops before the second longitudinal edge. In other words, the notch stops above the first region.

According to an embodiment, the notch stops before the active area.

According to an embodiment, the notch extends, for example stops, above the active area.

According to an embodiment, the opening extends all the way to the first longitudinal edge, so that the second region is in two parts separated by the opening.

According to an embodiment, the second region extends beyond the second longitudinal edge in the second direction, and the first region extends beyond the third longitudinal edge in the second direction.

According to an embodiment, the second region further extends on either side of the first region in the second direction, a first width of the first region being smaller than a second width of the second region.

According to an embodiment, the MOSFET transistor comprises a first contact on the first region and at least one second contact on the second region, for example a second contact for each part of a second region in two parts.

According to an embodiment, the MOSFET transistor further comprises at least one shared contact astride the first region and the second region, for example a shared contact for each part of a second region in two parts.

According to an embodiment, the first contact, or the at least one shared contact, is positioned at least partially in the opening.

According to an embodiment, the first region of the gate structure is between the drain region and the source region.

According to an embodiment, the second region of the gate structure is between the drain region and the source region.

According to an embodiment, the drain region and the source region are each comprised in a lightly-doped drain region at least partially located under the second region of the gate structure.

According to an embodiment, the active area is surrounded by insulating trenches, the first and second regions also extending above said insulating trenches.

According to an embodiment, the first and second regions of the gate structure comprise, for example, are made of, polysilicon.

According to an embodiment, the MOSFET transistor is a transistor for medium voltages, for example between 10 and 13 volts, or a transistor for high voltages, for example higher than 14 volts.

An embodiment provides a method of manufacturing at least one MOSFET transistor, the method comprising the following successive steps, for each MOSFET transistor: the forming of a first region of a gate structure, said first region being insulated and above an active area of a semiconductor substrate extending along a plane, said first region having a first length in a first direction of the plane; the forming of a second region of the gate structure, said second region being insulated and above the first region, having a second length greater than the first length, and further extending on either side of the first region in the first direction, the second region being formed so that a first longitudinal edge of said second region reaches the limit of, or extends beyond, a second longitudinal edge of the first region, in a second direction of the plane perpendicular to the first direction, and the forming of the second region comprising the formation of an opening in said second region, in the second direction from a third longitudinal edge of said second region opposite to the first longitudinal edge; then the forming of drain and source regions on either side of the second region in the first direction.

According to an embodiment, the first region of the gate structure is positioned on a gate insulator layer and is overlaid by an inter-gate insulator layer, and the second region of the gate structure is positioned astride, at least in the first direction, the first region overlaid by the inter-gate insulator layer and the gate insulator layer.

According to an embodiment, the opening is a notch that stops before the second longitudinal edge.

According to an embodiment, the opening extends all the way to the first longitudinal edge, so that the second region is separated in two parts by the opening.

According to an embodiment, the manufacturing method further comprises, after the forming of the first region, and before the forming of the second region, the forming of lightly-doped drain regions on either side of the first region in the first direction.

According to an embodiment, the manufacturing of the at least one MOSFET transistor comprises the manufacturing of a plurality of MOSFET transistors of different types selected from among: a medium-voltage transistor, and/or a high-voltage transistor, and/or a state transistor of a memory cell, and/or a memory cell selection transistor.

According to an embodiment, the first regions of said transistors are formed simultaneously.

According to an embodiment, the first regions of said transistors are made of the same material.

According to an embodiment, the second regions of said transistors are formed simultaneously.

According to an embodiment, the second regions of said transistors are made of the same material.

According to an embodiment, the manufacturing method comprises, prior to the forming of the first regions of the MOSFET transistors, the forming of gate insulator layers of the same material and of substantially the same thickness over the active areas of the MOSFET transistors.

According to an embodiment, the manufacturing method comprises, after the forming of the first regions and before the forming of the second regions of the MOSFET transistors, the forming of oxide-nitride-oxide layers of substantially the same thickness on the first regions of the MOSFET transistors.

An embodiment provides an electronic circuit comprising a semiconductor substrate and at least one MOSFET transistor such as described in the foregoing.

According to an embodiment, the electronic circuit is a non-volatile memory of electrically erasable and programmable type.

According to an embodiment, the at least one MOSFET transistor comprises a plurality of MOSFET transistors of different types selected from among: a medium-voltage transistor, and/or a high-voltage transistor, and/or a state transistor of a memory cell, and/or a memory cell selection transistor. The first regions of said transistors preferably being made of the same material, the second regions of said transistors being preferably made of the same material; and/or oxide-nitride-oxide layers of substantially the same thickness being positioned between the first regions and the second regions of said transistors; and/or gate insulator layers of the same material and of substantially the same thickness being positioned between the active areas and the first regions of said transistors.

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail. In particular, not all the steps of the MOS transistor manufacturing method have been described, as they can be carried out with usual methods of microelectronics. Similarly, not all the details of the MOS transistors have been described. In particular, not all the contacts and interconnection circuits of the transistors are shown. Further, not all the applications that the described MOS transistors are detailed.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front,” “back,” “top,” “bottom,” “left,” “right,” etc., or relative position qualifiers, such as the terms “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

In the following description, the qualifiers “insulating” and “conductive” respectively mean, unless otherwise specified, electrically insulating and electrically conductive.

In the following description, in order to alleviate it, a MOSFET-type transistor may be referred to as a MOS transistor, or transistor.

When reference is made to an “active area,” it is referred to an area of a semiconductor substrate of a transistor, for example, an area bounded by insulating regions, such as insulating trenches. An active area typically comprises a source region, a drain region, and a channel-forming region, or channel region, between the source region and the drain region.

A semiconductor substrate may be a solid substrate, for example, made of silicon, a semiconductor layer of a silicon-on-insulator (SOI) substrate, or a semiconductor well.

In the following description, a length corresponds to a dimension in a first direction, or longitudinal direction, corresponding to the X direction marked in the drawings, of an XY plane. The plane substantially corresponds to the main plane of the semiconductor substrate inside and on top of which the transistor is formed. The first direction X corresponds to a direction parallel to the conduction direction of the transistor, that is, the direction of the channel-forming region between the source and drain regions of the transistor. A width corresponds to a dimension in a second direction, or transverse direction, of the XY plane, corresponding to the Y direction indicated in the drawings, orthogonal to the first direction. A thickness or depth corresponds to a dimension in the direction perpendicular to the XY plane, corresponding to the vertical direction Z indicated in the figures. The term longitudinal refers to the first direction X, while the term transverse refers to the second direction Y.

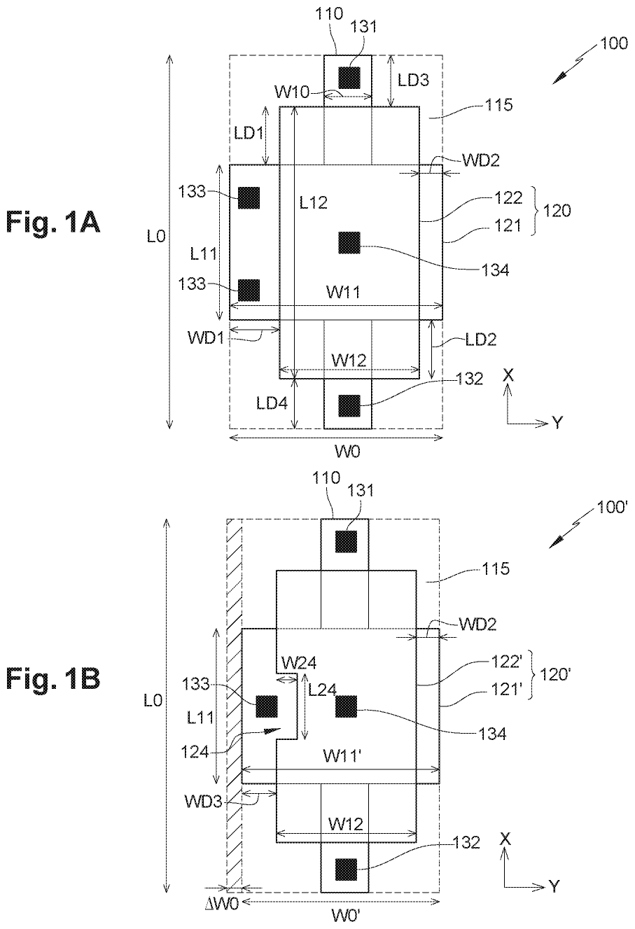

FIG. 1A shows, in a simplified and partial top view, an example of a MOS transistor 100. MOS transistor 100, of MV or HV type, is located inside and on top of an active region 110 of a semiconductor substrate. Active area 110 is surrounded by an insulating trench 115, for example of “Shallow Trench Isolation” (STI) type. Active area 110 comprises a doped drain region coupled to a contact 131 and a doped source region coupled to a contact 132. The drain region and the source region are separated by a channel region, all these regions being formed in the semiconductor substrate. Conventionally, the drain and source regions are generally silicided at least under contacts 131, 132.

In the case of an NMOS transistor, the drain and source regions are N-doped. They are P-doped for a PMOS transistor.

Transistor 100 also comprises a gate structure 120 insulated from active region 110 by a gate insulator layer (not shown), for example an oxide layer.

Gate structure 120 comprises a first region 121, of length L11 and of width W11, located above active area 110, insulated from the semiconductor substrate by the gate insulator layer. Gate structure 120 also comprises a second region 122, of length L12 and of width W12, located above first region 121 and insulated therefrom by another insulating layer (not shown), which may be a so-called ONO, for Oxide-Nitride-Oxide, layer. This ONO layer results from the fact that, generally, MOSFET transistors of MV or HV type are formed with manufacturing steps common to those of other transistors of floating-gate type, which comprise this ONO layer, and this, in order to decrease the number of total manufacturing steps.

For example, the first region 121 is adapted to the control of the transistor, while the second region 122 enables to adjust the breakdown voltage of the transistor, in particular by varying the lengths of the extensions LD1 and LD2 described hereafter.

Length L11 is smaller than length L12, and the second region 122 further extends on either side of the first region 121 in the longitudinal direction X (first direction). In other words, the second region 122 has a central area on the first region 121 and two parts LD1 and LD2 further extending on either side of the first region 121 in direction X.

The length L12 of the second region 122 is thus equal to the sum of the length L11 of the first region 121 and of extensions LD1 and LD2.

Extensions LD1 and LD2 in the X direction of the second region 122 enable, during the doping of drain and source regions, to modify the doping profile, in particular to increase the distance between the drain and source regions, since this doping takes place after the forming of the second region 122. This enables to modify the electrical characteristics of transistor 100, in particular to increase its breakdown voltage (BV).

Extensions LD1 and LD2 may be substantially equal to each other.

Active area 110 extends on either side of the second region 122 in the longitudinal direction X, having an extension LD3 on the drain side and an extension LD4 on the source side, which two extensions LD3 and LD4 may be similar. Thus, the length of active area 110, which in this example is equal to the length L0 of MOS transistor 100, is greater than the length L12 of the second region 122. This enables to have portions of active area 110 accessible for contacts 131 and 132. The length L0 of active area 110 is equal to the sum of length L12 and of extensions LD3 and LD4.

The width W11 of the first region 121 is greater than the width W12 of the second region 122, and the first region 121 further extends on either side of the second region 122 in the transverse direction Y (second direction). In other words, the first region 121 has a central area under the second region 122 and two parts WD1 and WD2 further extending on either side of the second region 122 in the transverse direction Y.

The width W11 of the first region 121 is thus equal to the sum of the width W12 of the second region 122 and of extensions WD1 and WD2.

At least one of extension WD1 and WD2 enables, in particular, to form an electrical connection of the first region 121. Two contacts 133 on the first region 121, and one contact 134 on the second region 122 have for example been shown, which number may vary, and the contacts being generally formed on silicided portions of these gate regions.

The width W12 of the second region 122 is itself greater than the width W10 of active area 110, the second region 122 extending on either side of active area 110 in the transverse direction Y, this, in particular, in order to draw away the implantations, in active area 110, of the source region and of the drain region, achieved after the forming of the second region 122, the non-implanted portion of active area 110, under the second region 122, having to remain lightly doped. Therefore, since the first region 121 extends on either side of the second region 122 in the transversal direction Y, the first region 121 also extends on either side of the active area 110 in the transversal direction Y.

The manufacturing of a MOS transistor generally complies with design rules, particularly in terms of contact positioning, in terms of distance between the contacts and the edges of the regions that they connect, and/or between the contacts and other regions, or even between the gate regions of two adjacent MOS transistors, for example to avoid risks of short-circuit or leakage current, and/or to limit the forming of parasitic capacitances. For example, each contact 133 of the first region 121, which is insulated from active region 110 only by the gate insulator layer, generally needs to respect a minimum limit for the distance from the edges of this first region 121, to ensure that this contact does not further extend beyond the edges of this first gate region, taking into account a risk of misalignment during manufacturing, and/or preferably needs to be positioned outside active area 110, to avoid any risk of short-circuit between contact 133 and active area 110, which may be formed accidentally during the transistor manufacturing. Further, a minimum distance needs to be respected between each contact 133 of the first region 121 and the second region 122.

The first and second gate regions 121 and 122 are generally made of an identical material, for example polysilicon.

In general, the second region 122, or even the exposed portions of the first region 121, comprise on their flanks lateral insulating regions, or spacers (not shown).

The two gate regions 121 and 122 are in this example coupled together, for example by their contacts 133, 134 and a metallization located in a first metal level of an interconnection structure, or BEOL, (not shown).

According to a non-limiting example, extensions LD1 and LD2 are each equal to approximately 260 nm, the length L11 of the first region 121 is equal to approximately 700 nm, the length L12 of the second region 122 is equal to approximately 1.22 μm, extension WD1 is equal to approximately 260 nm, extension WD2 is equal to approximately 100 nm, the width W12 of the second region 122 is equal to approximately 620 nm, the width W11 of the first region 121 is equal to approximately 980 nm, the extension LD3 and LD4 of active area 110 are equal to approximately 225 nm, and the width W10 of active area 110 is equal to approximately 220 nm. These dimensions are taken as a non-limiting example, in particular with the purpose of further indicating the gains in surface footprint which are allowed by the various embodiments described in the following.

It can be observed that, given the design rules, to form a MOS transistor of MV or even HV type, the surface footprint of this MOS transistor is significant, as is that of an electronic device which comprises a plurality of MOS transistors, for which spacing rules between MOS transistors may apply. For example, it may be desired to provide a spacing of 0.20 μm in the Y direction and 0.50 μm in the X direction.

Taking the dimensions given hereabove as an example, MOS transistor 100 occupies a width W0 of approximately 0.98 μm and a length L0 of approximately 1.67 μm, that is, a surface footprint of approximately 1.63 μm², and this, not including the minimum spacings between transistors (taking into account the spacings given hereabove as an example, a surface footprint of approximately 2.56 μm² can be achieved).

It is desired to decrease this surface footprint, while complying with the design rules.

FIG. 1B shows, in a simplified and partial top view, another example of a MOS transistor 100′, of MV or HV type, which differs from transistor 100 mainly in that the second region 122′ comprises a notch 124 opposite the contact 133 of the first region 121. This notch 124 enables to bring contact 133 closer to the second region 122′ in the transverse direction Y, and thus to decrease extension WD1, which becomes WD3, while respecting the other dimensions and in particular while respecting the design rules. Notch 124 has a width W24 smaller than the width W12 of second region 122′ of the gate structure 120′, and it stops before active area 110, and a length L24 smaller than the length L11 of first region 121.

Thus, it can be seen that the width W11′ of the first region 121′, and thus the width W0′ of MOS transistor 100′, and its surface footprint, can be decreased. In other words, the width W11′, respectively the width W0′, of FIG. 1B is smaller than the width W11, respectively the width W0, of FIG. 1A, all other dimensions being comparable. The width decrease ΔW0 of MOS transistor 100′ is, for example, in the range from 80 to 100 nm.

Taking the example of dimensions indicated hereabove, with a width decrease ΔW0 of 80 nm, MOS transistor 100′ occupies a width W0′ of approximately 0.9 μm and a length L0 of approximately 1.67 μm, that is, a surface footprint of approximately 1.50 μm², not counting the minimum spacings between transistors, which allows for a surface gain of approximately 8% as compared with the MOS transistor 100 of FIG. 1A.

However, it is desired to further decrease this surface footprint, and this, while still complying with the design rules, and without altering the expected electrical performance of the MOS transistor, in particular for MV and HV MOS transistors.

The inventors provide a MOS transistor enabling to meet the previously-described improvement needs, and to overcome all or part of the disadvantages of the previously-described MOS transistors.

Embodiments of MOS transistors will be described hereafter. The described embodiments are not limiting and various variants and/or combinations of embodiments will occur to those skilled in the art based on the indications of the present disclosure.

Preferably, in the embodiments described hereafter, the first region extends on either side of the active area in the transversal direction Y, and the second region extends on either side of the active area in the transversal direction Y.

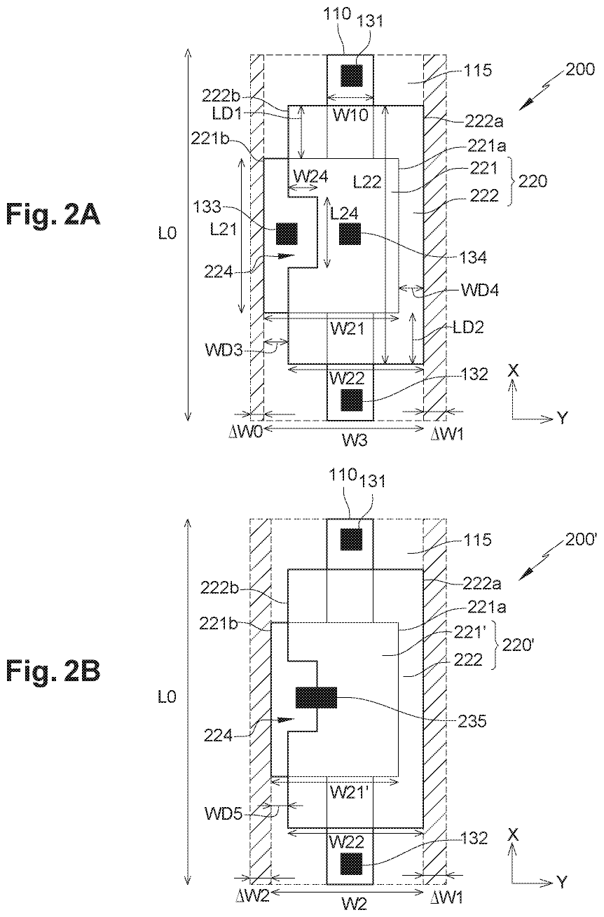

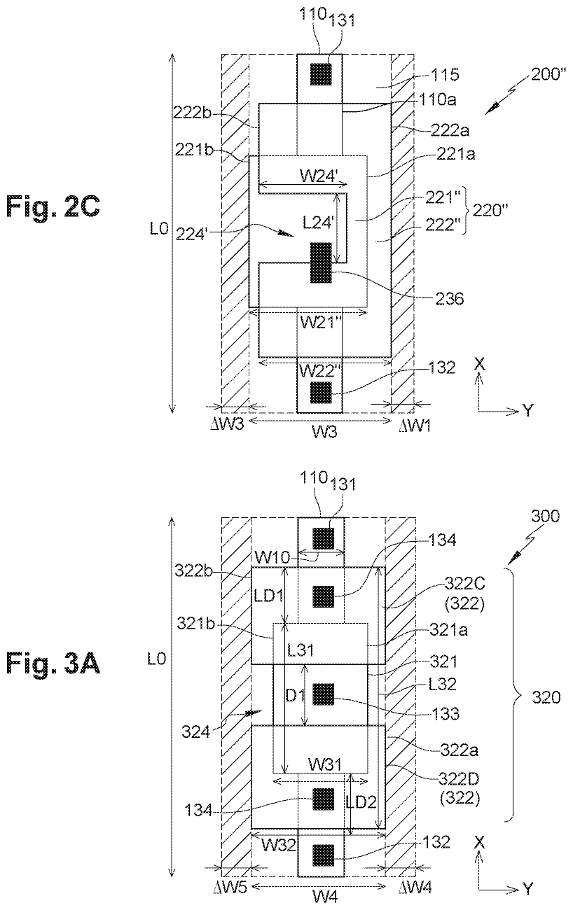

FIG. 2A shows, in a simplified and partial top view, a MOS transistor 200 according to an embodiment.

MOS transistor 200 comprises many elements in common with the MOS transistor 100′ of FIG. 1B. These common elements keep the same numerical references and will not be detailed again in the following.

Similarly to the MOS transistor 100′ of FIG. 1B, MOS transistor 200 comprises an active area 110, surrounded by insulating trenches 115, and a gate structure 220 insulated from active area 110 by a gate insulator layer (not shown), for example an oxide layer. Gate structure 220 comprises a first region 221 having a length L21 and a second region 222 located above the first region 221 and insulated therefrom by another insulating layer (not shown), which may be a so-called ONO, for Oxide-Nitride-Oxide, layer. The second region 222 has a length L22 greater than length L21. The second region 222 has a central area under the first region 221 and two parts LD1 and LD2 further extending on either side of the first region 221 in the longitudinal direction X (first direction).

The MOS transistor 200 of FIG. 2A differs from the MOS transistor 100′ of FIG. 1B mainly in that the second region 222 extends beyond at least one longitudinal edge 221a of the first region 221 in the transverse direction Y (second direction). In other words, the longitudinal edge 222a of the second region 222 extends in the Y direction beyond a longitudinal edge 221a of the first region 221. Thus, as compared with the MOS transistor 100′ of FIG. 1B, the extension WD2 of the first region 121 relative to the second region 122 in the Y direction is removed, which creates a decrease in width ΔW1 at least equal to extension WD2. On the other hand, an extension WD4 of the second region 222 with respect to the first region 221 in the transverse direction Y is formed.

Thus, the width W21 of the first region 221, respectively the width W1 of MOS transistor 200, is smaller than the width W11′ of the first region 121, respectively the width W0′ of MOS transistor 100′, all other dimensions being comparable.

The designer may decrease the width of the first region 221, that is, increase extension WD4, as long as they observe that this does not interfere with the operation of MOS transistor 200.

Further, given that the widths are modified to decrease the surface area, it is possible to keep the same length L21 of the first region 221, the same length L22 of the second region 222, as well as the same extensions LD1 and LD2 of the second region 222, which enables to maintain the performance/operating points of MOS transistor 200, particularly as compared with the MOS transistor 100′ of FIG. 1B.

Similarly to the MOS transistor 100′ of FIG. 1B, the second region 222 has a notch 224 facing the longitudinal edge 221b, opposite to the longitudinal edge 221a, of the first region 221. Notch 224 is similar to the notch 124 of FIG. 1B, and it also faces contact 133 on the first region 221, enabling to bring this contact 133 closer to the second region 222. Notch 224 extends from the longitudinal edge 222b of the second region 222, opposite to longitudinal edge 222a, it has a width W24 smaller than the width W22 of the second region 222.

Preferably, notch 224 stops before the longitudinal edge 221a of the first region 221. This enables to avoid a void between the first region 221 and the second region 222, and thus, for example, to avoid the formation of a charge strap and/or any insertion in the void, which could induce defectivity issues and/or compromise the reliability of the MOS transistor.

Preferably, notch 224 stops before active area 110. This enables, for example, to align contacts 131, 132, 134 in the X direction, and thus to have a same width of metallization coupled to these contacts, favoring the compactness of the interconnexion structure (BEOL).

For example, notch 224 has a length L24 smaller than the length L21 of the first region 221. Notch 224 enables to maintain the width decrease ΔW0 of the transistor 100′ of FIG. 1B.

Taking the example of dimensions indicated hereabove, with a width decrease ΔW1 equal to WD2, that is, 100 nm, MOS transistor 200 occupies a width W1 of approximately 0.8 μm and a length L0 of approximately 1.67 μm, that is, a surface footprint of approximately 1.33 μm², not counting the minimum spacing between transistors, that is, a gain in surface area of approximately 11% as compared with the MOS transistor 100′ of FIG. 1B.

In this embodiment, the first region 221 further extends, on the side of its longitudinal edge 221b opposite to longitudinal edge 221a, beyond the second region 222 in the transverse direction Y similarly to the MOS transistor 100′ of FIG. 1B. This is not limiting, as shown by other embodiments described hereafter.

As an alternative to the embodiment shown in FIG. 2A, it would be possible for the second region 222 not to extend beyond the first region 221, but to be at the limit of the longitudinal edge 221a of the first region 221 in the transverse direction Y. In other words, the longitudinal edge 222a of the second region 222 could be positioned at the same level in the Y direction as the longitudinal edge 221a of the first region 221. In other words, extension WD4 could be equal to zero. This would maintain a width decrease ΔW1 equal to WD2.

The first and second gate regions 221 and 222 are preferably connected to each other, for example via the contacts 133, 134 of these gate regions and a metallization located in a metallization level of an interconnection structure (not shown), for example a first metal level.

FIG. 2B shows, in a simplified and partial top view, a MOS transistor 200′ according to an alternative embodiment of the MOS transistor 200 of FIG. 2A.

MOS transistor 200′ has many elements in common with the MOS transistor 200 of FIG. 2A, these common elements keep the same numerical references and will not be detailed again in the following.

The MOS transistor 200′ of FIG. 2B differs from the MOS transistor 200 of FIG. 2A mainly in that, instead of having a contact 133 on the first region 221 and a separate contact 134 on the second region 222, a shared contact 235 is provided astride, in the transverse direction Y, the first region 221′ and the second region 222 of gate structure 220′. Shared contact 235 corresponds, for example, to a double contact. The connection of shared contact 235 to the first region 221′ is performed in notch 224, which is similar to notch 224 of FIG. 2A.

For example, the shared contact 235 has a width, in the Y direction, comprised between 2 and 3 times the width of a single contact of the type of contacts 131 and 132. For example, the width of the shared contact 235 in the Y direction is equal to around 2 times the width of the single contact for a dense electronic device, or is comprised between 2.5 and 3 times the width of the single contact for a less dense electronic device. For example, the shared contact 235 has a length in the X direction, substantially equal to the length of the single contact.

This variant enables to further decrease, as compared with the embodiment of FIG. 2A, the width W21′ of the first region 221′, and thus accordingly the width W2 of MOSFET transistor 200′ (width decrease ΔW2 greater than ΔW0). Thus, the width W21′ of the first region 221′, respectively the width W2 of MOSFET transistor 200′, is smaller than the width W21 of the first region 221, respectively the width W1 of MOSFET transistor 200, all other dimensions being comparable. Extension WD3 is thereby also decreased and becomes WD5.

Taking the example of dimensions indicated hereabove, with a width decrease ΔW2 equal to approximately 60 nm, MOS transistor 200′ occupies a width W2 of approximately 0.74 μm and a length L0 of approximately 1.67 μm, that is, a surface footprint of approximately 1.23 μm², not counting the minimum spacings between transistors, that is, a gain in surface area of approximately 18% as compared with the MOS transistor 100′ of FIG. 1B.

In the embodiment of FIG. 2B, the second region 222 is substantially similar to that of FIG. 2A.

FIG. 2C shows, in a simplified and partial top view, a MOS transistor 200″ according to another alternative embodiment of the MOS transistor 200 of FIG. 2A.

MOS transistor 200″ has many elements in common with the MOS transistor 200 of FIG. 2A, these common elements keep the same numerical references and will not be detailed again in the following.

The MOS transistor 200″ of FIG. 2C differs from the MOS transistor 200 of FIG. 2A mainly in that the notch 224′ of the second region 222″ of gate structure 220″ extends, in the transverse direction Y, at least up to above active area 110, or at an edge 110a of the active area 110 closest to the longitudinal edge 221a, or slightly beyond that edge 110a, so that the contact 236 of the first region 221″ of gate structure 220″ can be positioned opposite active area 110. For example, contacts 131, 132, 236 are substantially aligned in the X direction. This enables, in particular, the metallization, for example the first metal level of the interconnection structure (BEOL), which couples contacts 131, 132, and 236, to have substantially the same width along the X direction, favoring the compactness of the interconnexion structure and thus making MOS transistor 200″ more compact in the Y direction. Thus, notch 224′ has a width W24′ which is greater than the width W24 of the notch 224 of FIGS. 2A and 2B, while its length L24′ may be equal to or different from the length L24 of the notch 224 of FIGS. 2A and 2B.

Like notch 224 of FIG. 2A, preferably, notch 224′ stops before the longitudinal edge 221a of the first region 221″. This enables to avoid a void between the first region 221″ and the second region 222″, and thus, for example, to avoid the formation of a charge strap and/or any insertion in the void, which could induce defectivity issues and/or compromise the reliability of the MOS transistor.

This variant also enables to further decrease, as compared with the embodiment of FIG. 2B, the width W21″ of the first region 221″, and thus accordingly the width W3 of MOSFET transistor 200″ (width decrease ΔW3 greater than ΔW2). Thus, the width W21″ of the first region 221″, respectively the width W3 of MOSFET transistor 200″, is smaller than the width W21′ of the first region 221′, respectively the width W2 of MOSFET transistor 200′, all other dimensions being comparable.

Further, in this example, a shared contact 236 astride, in the longitudinal direction X, the first region 221″ and the second region 222″ is provided. As a variant, a shared contact in the transverse direction Y, or one contact on the first region 221″ and another separate contact on the second region 222″ could be provided. As a variant, shared contact 236 may not be above active area 110.

For example, the shared contact 236 has a length, in the X direction, comprised between 2 and 3 times the length of a single contact of the type of contacts 131 and 132. For example, the length of the shared contact 236 in the X direction is equal to around 2 times the length of the single contact for a dense electronic device, or is comprised between 2.5 and 3 times the length of the single contact for a less dense electronic device. For example, the shared contact 236 has a width in the Y direction, substantially equal to the width of the single contact.

Taking the example of dimensions indicated hereabove, with a width decrease ΔW3 equal to approximately 80 nm, MOS transistor 200″ occupies a width W3 of approximately 0.72 μm and a length L0 of approximately 1.67 μm, not counting the minimum spacings between transistors, that is, a surface footprint of approximately 1.20 μm², and a gain in surface area of approximately 20% as compared with the MOS transistor 100′ of FIG. 1B.

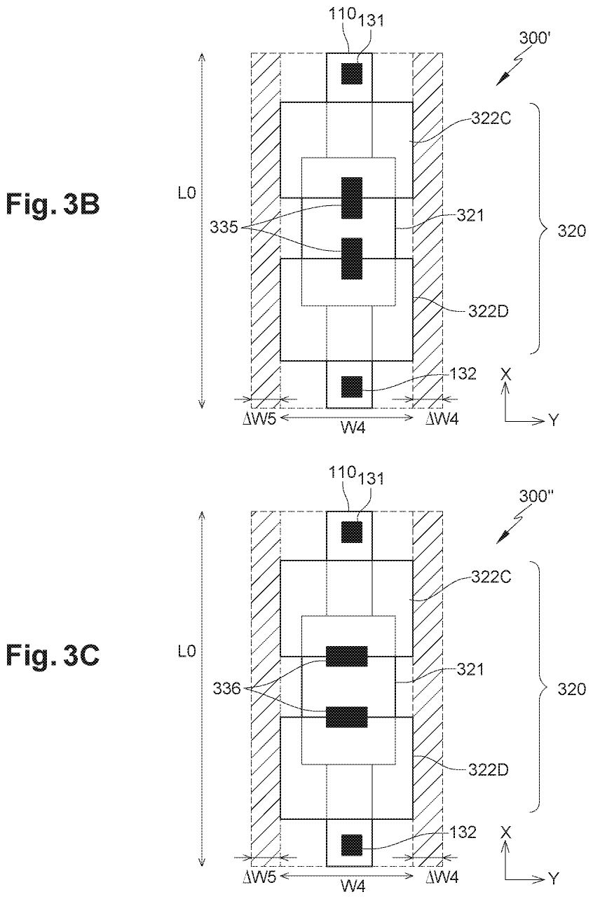

FIG. 3A shows, in a simplified and partial top view, a MOS transistor 300 according to another embodiment.

MOS transistor 300 has many elements in common with the MOS transistor 200 of FIG. 2A, these common elements keep the same numerical references and will not be detailed again in the following.

In particular, similarly to the MOS transistor 200 of FIG. 2A, MOS transistor 300 comprises an active area 110 and a gate structure 320 insulated from active area 110 by a gate insulator layer (not shown), for example an oxide layer. Gate structure 320 comprises a first region 321 having a length L31 and a second region 322 located above the first region 321 and insulated therefrom by another insulating layer (not shown), which may be a so-called ONO, for Oxide-Nitride-Oxide, layer. The second region 322 has a total length L32 greater than the length L31 of the first region 321. The second region 322 has extensions LD1 and LD2 on either side of the first region 321 in the longitudinal direction X (first direction).

The MOS transistor 300 of FIG. 3A differs from the MOS transistor 200 of FIG. 2A mainly in that the second gate region 322 is in two distinct parts, a first part 322C and a second part 322D, separated from each other by a non-zero distance D1 in the longitudinal direction X. Further, the second region 322 extends on either side of the first region 321 in the transverse direction Y. The width W31 of the first region 321 is smaller than the width W32 of the second region 322.

This embodiment enables to form the contacts 133, 134 of the first and second regions in the opening 324 between the two parts 322C and 322D of the second gate region 322. Thus, preferably, a distance D1 which enables to respect the minimum distances, according to the design rules, between the contact 133 on the first region 321 and each part 322C, 322D of the second region 322, is selected. Each part 322C, 322D has its own contact 134.

This embodiment enables to still further decrease, as compared with the embodiment of FIG. 2A, and even with the embodiments of FIGS. 2B and 2C, the width W31 of the first region 321, and this, both on the side of the longitudinal edge 321a (width decrease ΔW4) and on the side of the longitudinal edge 321b (width decrease ΔW5) of the first region 321. This configuration thus enables to accordingly decrease the width W4 of MOSFET transistor 300. Thus, the width W31 of the first region 321, respectively the width W4 of MOSFET transistor 300, is smaller than the width W21 of the first region 221, respectively the width W1, of MOSFET transistor 200, all other dimensions being comparable.

The opening 324 between the two parts 322C and 322D of the second region 322 can be seen as an extension of the notch 224 or 224′ of FIGS. 2A, 2B and 2C between the two longitudinal edges 322a and 322b of the second region 322 so as to separate the second region 322 into these two parts.

The two parts 322C and 322D preferably have the same width, equal to the width W32 of the second region 322. The two parts 322C and 322D may have, or not, the same length. The total length L32 of the second region 322 is equal to the sum of the lengths of the two parts 322C and 322D and of the distance D1 between these two parts.

Taking the example of dimensions indicated hereabove, with ΔW4 and ΔW5 equal to approximately 80 nm, that is, a width decrease equal to 160 nm, MOS transistor 300 alone occupies a width W4 of approximately 0.64 μm and a length L0 of approximately 1.67 μm, that is, a surface footprint of approximately 1.7 μm², not counting the minimum spacings between transistors, that is, a surface gain of approximately 20% as compared with the MOS transistor 200 of FIG. 2A, and of approximately 29% as compared with the MOS transistor 100′ of FIG. 1B.

Further, given that the widths are modified to decrease the surface area, it is possible to keep the same length L31 of the first region 321, the same length L32 of the second region 322, as well as the same extensions LD1 and LD2 of the second region 322 (extension LD1 of the first part 322C and extension LD2 of the second part 322D), which enables to keep the performance/operating points of MOS transistor 300, in particular as compared with the MOS transistor 100′ of FIG. 1B.

The first and second gate regions 321 and 322 are preferably connected to each other, for example by the contacts 133, 134 of these gate regions and a metallization located in a metallization level of an interconnection structure (not shown), for example a first metal level.

For example, contacts 131, 132, 133, 134 are substantially aligned in the X direction. This enables, in particular, the metallization coupled to these contacts to have substantially the same width, favoring the compactness of the interconnexion structure.

FIG. 3B shows, in a simplified and partial top view, a MOS transistor 300′ according to an alternative embodiment of the MOS transistor of FIG. 3A.

MOS transistor 300′ has many elements in common with the MOS transistor 300 of FIG. 3A, these common elements keep the same numerical references and will not be detailed again in the following.

The MOS transistor 300′ of FIG. 3B differs from the MOS transistor 300 of FIG. 3A mainly in that, instead of having a contact 133 on the first region 321 and a separate contact 134 on each of the parts 322C and 322D of the second region 322, a shared contact 335 is provided astride, in the longitudinal direction X, the first region 321 and each of the parts 322C and 322D of the second region 322.

For example, each shared contact 335 has a width, in the Y direction, comprised between 2 and 3 times the width of a single contact of the type of contacts 131 and 132. For example, the width of each shared contact 335 in the Y direction is equal to around 2 times the width of the single contact for a dense electronic device, or is comprised between 2.5 and 3 times the width of the single contact for a less dense electronic device. For example, each shared contact 335 has a length in the X direction, substantially equal to the length of the single contact.

This variant enables the metallization, for example the first metal level of the interconnection structure, which couples contacts 131, 132, and 335, to have substantially the same width along the X direction, thus making MOS transistor 300′ more compact in the Y direction. Width W4 could thus be decreased as compared with FIG. 3A and/or FIG. 3C described hereafter.

For example, contacts 131, 132, 235 are substantially aligned in the X direction. This enables, in particular, the metallization coupled to these contacts to have substantially the same width, favoring the compactness of the interconnexion structure.

FIG. 3C shows, in a simplified and partial top view, a MOS transistor according to an alternative embodiment of the MOS transistor of FIG. 3B.

MOS transistor 300″ has many elements in common with the MOS transistor 300′ of FIG. 3B, these common elements keep the same numerical references and will not be detailed again in the following.

The MOS transistor 300″ of FIG. 3C differs from the MOS transistor 300′ of FIG. 3B mainly in that, instead of a shared contact in the longitudinal direction X, a shared contact 336 is provided astride, in the transverse direction Y, the first region 321 and each of the parts 322C and 322D of the second region 322.

For example, each shared contact 336 has a length, in the X direction, comprised between 2 and 3 times the length of a single contact of the type of contacts 131 and 132. For example, the length of each shared contact 336 in the X direction is equal to around 2 times the length of the single contact for a dense electronic device, or is comprised between 2.5 and 3 times the length of the single contact for a less dense electronic device. For example, each shared contact 336 has a width in the Y direction, substantially equal to the width of the single contact.

For example, contacts 131, 132, 336 are substantially aligned in the X direction. This enables, in particular, the metallization coupled to these contacts to have substantially the same width, favoring the compactness of the interconnexion structure.

This variant enables to increase the contact areas of each shared contact 336 with both the first region 321 and the second region 322.

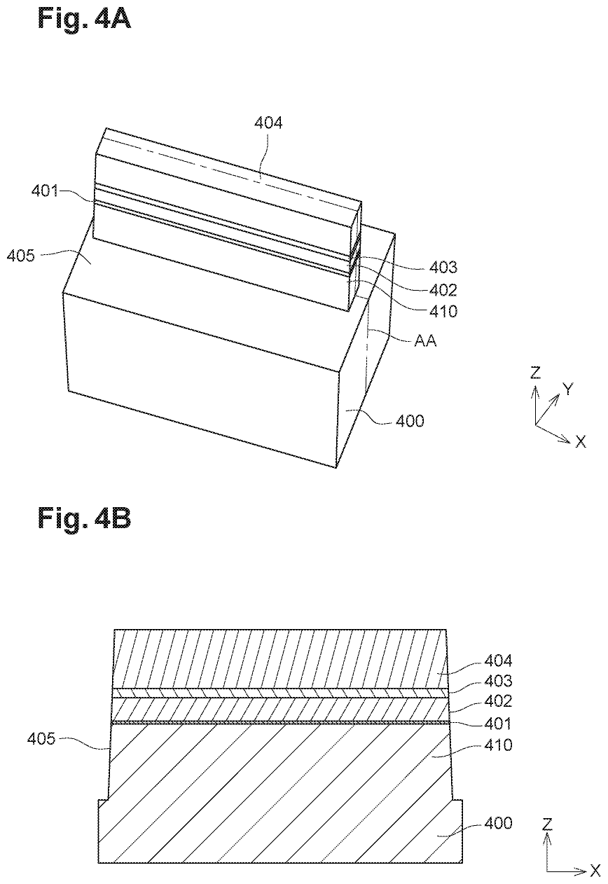

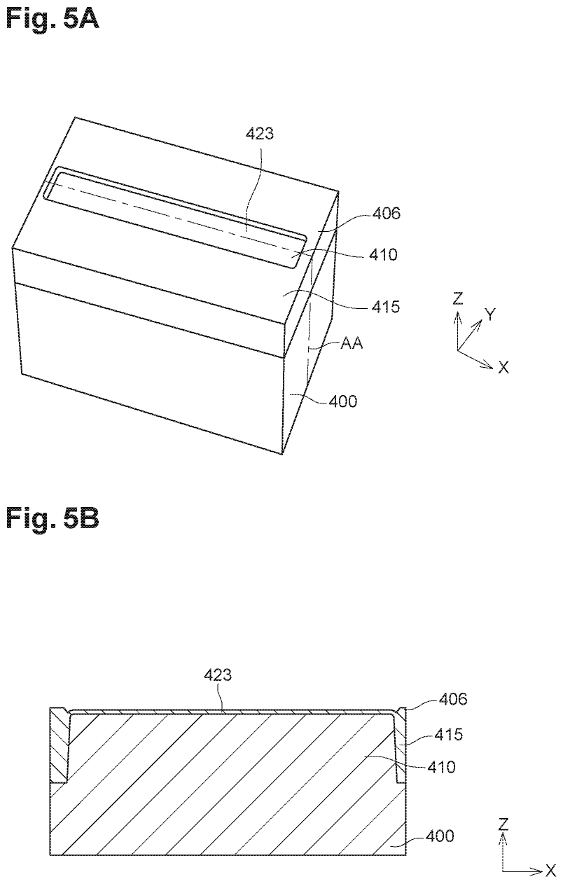

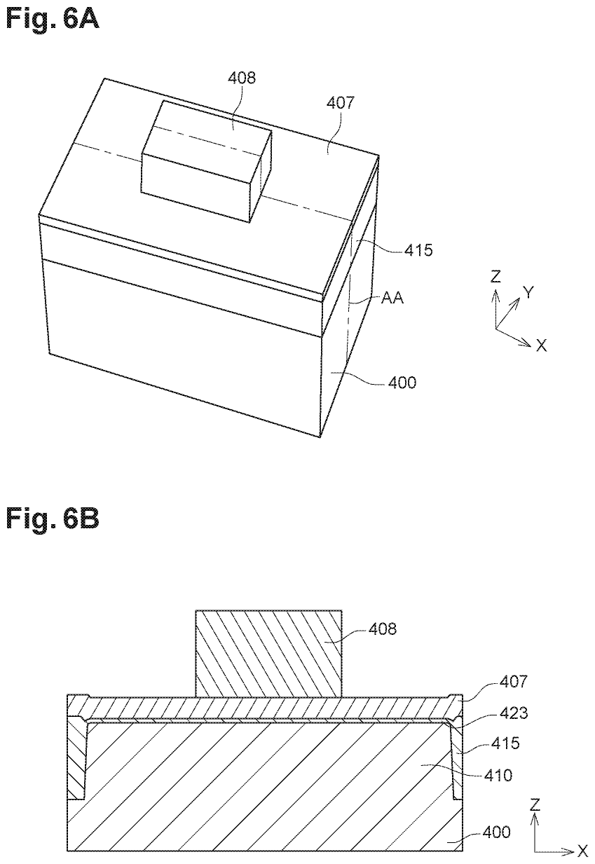

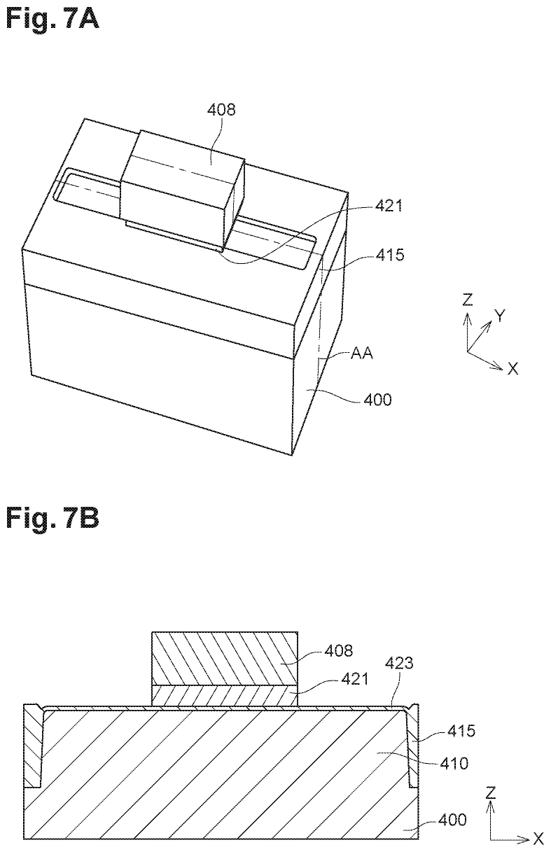

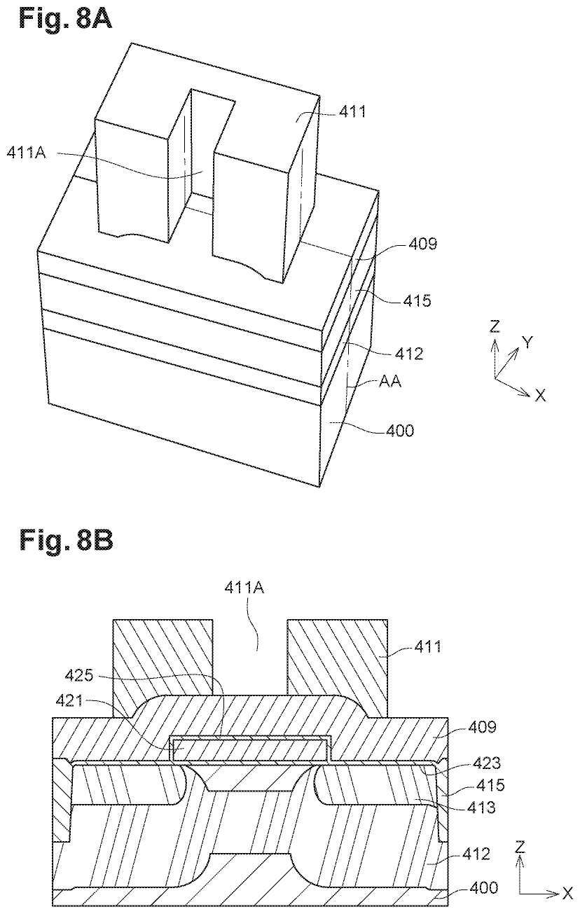

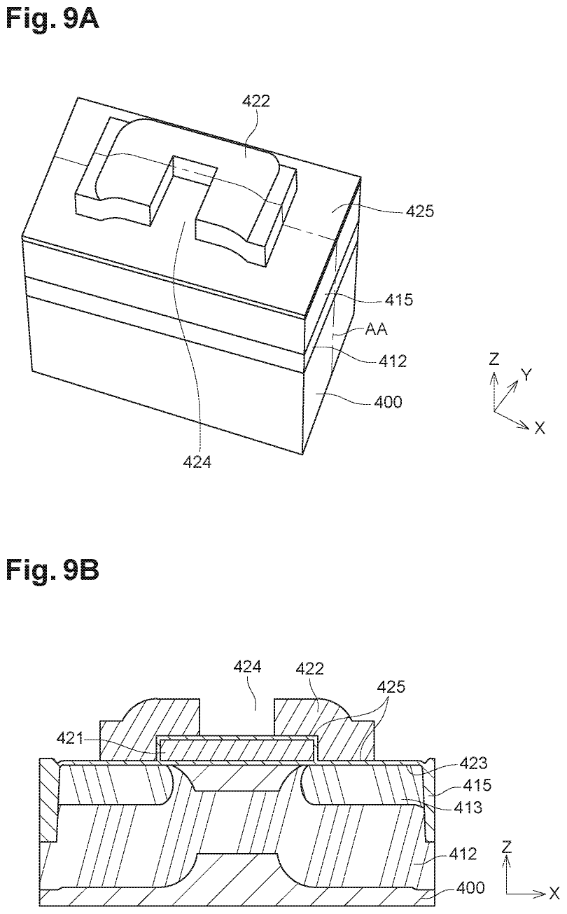

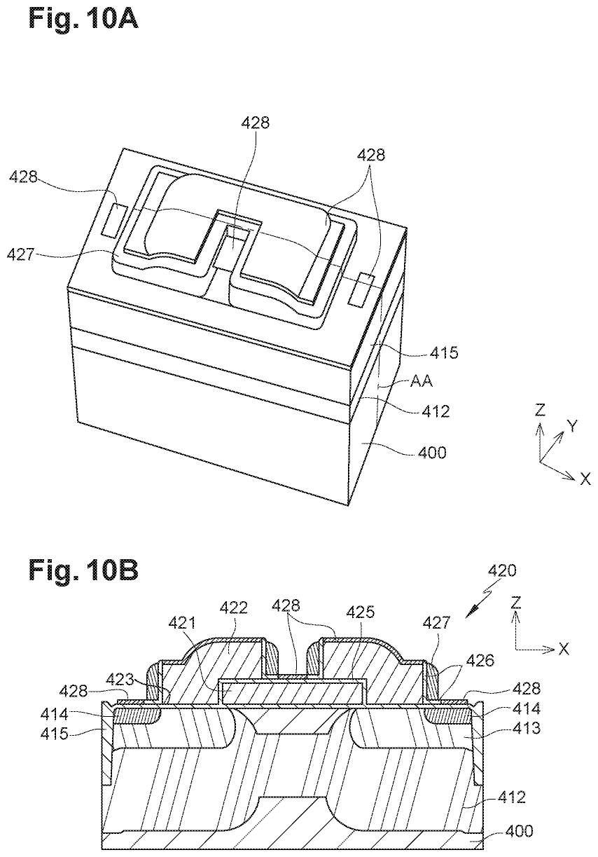

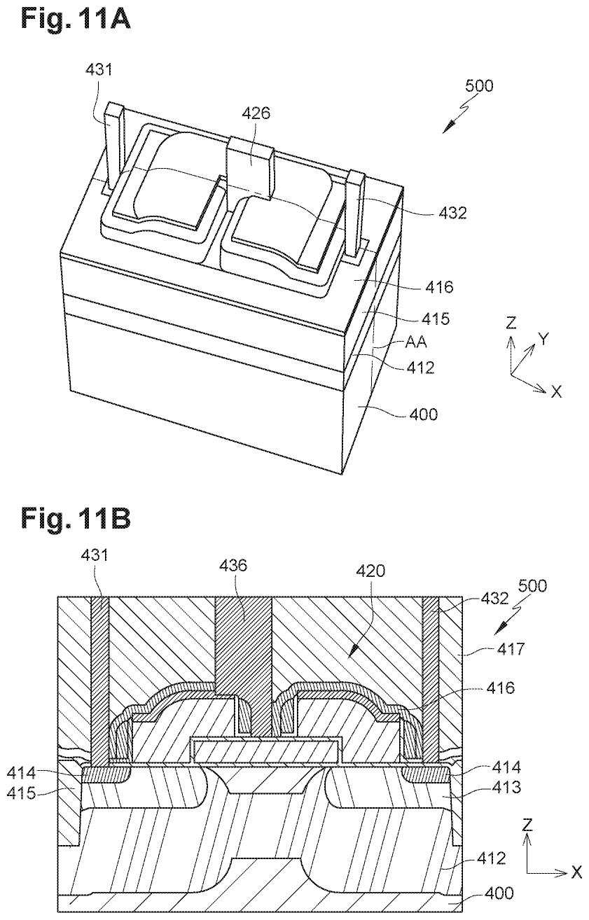

FIG. 4A, FIG. 4B, FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, and FIG. 11B are three-dimensional longitudinal cross-section views, partially and schematically illustrating successive steps of a method of manufacturing a MOS transistor according to an embodiment.

The longitudinal cross-sections are obtained along the cutting plane AA, as shown in the three-dimensional views.

FIGS. 4A and 4B illustrate an initial structure comprising a layer 401 of silicon oxide on a semiconductor substrate 400, a hard mask layer 402, for example, silicon nitride, on layer 401, a layer 403 of silicon oxide on layer 402, and an etch mask 404, for example photoresist, on layer 403.

An active area 410 surrounded by trenches 405 has been formed by etching through etch mask 404.

FIGS. 5A and 5B illustrate a structure obtained as a result of the removal of etch mask 404 and of layers 402, 403, or even silicon oxide layer 401, and of the deposition of another silicon oxide layer 406 on semiconductor substrate 400 and in trenches 405, forming a gate insulator layer 423, or gate insulator 423, on active region 410, and insulating trenches 415 around active area 410.

FIGS. 6A and 6B illustrate a structure obtained as a result of the deposition of a layer 407 of polycrystalline silicon, or polysilicon, on gate insulator layer 423 and insulating trenches 415, and of an etch mask 408, for example photoresist, on polysilicon layer 407.

FIGS. 7A and 7B illustrate a structure obtained as a result of the etching of polysilicon layer 407 through etch mask 408, forming a first region 421 of a gate structure 420 (shown in FIGS. 10A and 10B). Etch mask 408 is then removed.

FIGS. 8A and 8B illustrate a structure obtained as a result of the forming of a well 412 in semiconductor substrate 400 and of lightly-doped regions 413, or LDD, in well 412, followed by the deposition of an ONO-type insulator layer 425, or inter-gate insulator layer 425, on top and flanks of the first region 421, of a polysilicon layer 409 on the first region 421 insulated by the inter-gate insulator layer 425 and on the gate insulator layer 423, and of an etch mask 411, for example, photoresist, on polysilicon layer 409. The etch mask has an opening 411A above the first region 421, in the form of a notch in the Y direction, to form a future notch in polysilicon layer 409. The polysilicon layer 409 also extends on either side of, and around, the first region 421 in the X direction, on the gate insulator layer 423. In other words, the polysilicon layer 409 extends on the flanks of the first region 421 insulated by the inter-gate insulator layer 425.

FIGS. 9A and 9B illustrate a structure obtained at the end of the etching of polysilicon layer 409 through etch mask 411, forming a second region 422 of gate structure 420 (shown in FIGS. 10A and 10B). This etching allows forming, in the second region 422, a notch 424 which extends in the Y direction up to above the first region 421. Etch mask 411 is then removed. A notch 424 similar to notch 224′ of FIG. 2C has been represented, but notch 424 could be similar to notch 224 of FIG. 2A, or similar to notch 324 of FIG. 3A.

FIGS. 10A and 10B illustrate a structure obtained at the end of the forming of source and drain regions 414 in LDD regions 413, of the deposition of a silicon oxide layer 426 on the flanks of the second region 422 and on a portion of inter-gate insulator layer 425 around the second region 422, and then of the forming of silicon nitride spacers 427 on silicon oxide layer 426, and thus on the flanks of the second region 422.

Silicide layers 428 are then deposited on the source and drain regions 414, on an exposed portion of the first region 421 and on the second region 422. A gate structure 420 with a double gate region is obtained.

FIGS. 11A and 11B illustrate a structure obtained as a result of the forming of a silicon nitride layer 416 on the structure of FIGS. 10A and 10B, and then of an insulating layer 417 called PMD (Pre Metal Dielectric), which may be silicon oxide, on layer 416. Contacts are formed through PMD layer 417 and layer 416: two contacts 431 and 432 connect the silicided portions of source and drain regions 414, and a shared contact 436 connects both the first gate region 421 in slot 424 and the second gate region 422.

The resulting MOS transistor 500 is similar to the transistor 200″ of FIG. 2C. Those skilled in the art will know how to adapt the manufacturing method to obtain a MOS transistor according to any other embodiment.

It can be seen that first region 421 of gate structure 420 is positioned on gate insulator layer 423, is covered by inter-gate insulator layer 425, and second region 422 is positioned astride inter-gate insulator layer 425 and gate insulator layer 423. In particular, the second region 422 is positioned on either side of, and around, the first region 421 at least in the X direction. The first region 421 is not encapsulated within a single insulating layer. The second region 422 has at least a portion located above the first region 421. This allows the second region 422 to be in contact with the first region 421, and not to be floating. These characteristics also preferably apply to all the gate structures 220, 320 described above.

It is thus possible to manufacture a MOS transistor according to the embodiments by implementing a standard method of microelectronics, for example in a standard manufacturing line, and this, with no additional cost.

The MOSFET transistor according to the embodiments may be integrated in an electronic circuit, for example an integrated circuit. The MOSFET transistor according to the embodiments may form part of a non-volatile memory cell, for example an EEPROM-type memory. The MOSFET transistor according to the embodiments may in particular form a transistor of selection of an EEPROM-type memory cell.

Many applications are likely to benefit from the advantages provided by the MOSFET transistor according to the embodiments, and for example by an EEPROM-type memory comprising one or more of these MOSFET transistors, the MOSFET transistor thus being able to be incorporated in various types of devices.

As an example, the MOSFET transistor may be incorporated in a device intended for the automotive industry. The electrification of motor vehicles is causing a sharp increase in the number of electronic components present in vehicles. Further, driver assistance and driving automation are leading to an increase in the number of electronic components in vehicles. The decrease in the surface footprint of electronic components thus is an advantage.

As an example, the MOSFET transistor may be incorporated in a device for industrial use. In particular, the device is used, for example, for the development of green energies or for the infrastructure electrification, for example for charging stations or for solar energy collection. The device may also be used in the field of the Internet of Things or in the field of smart homes. The device may also be used for the implementation of cloud computing systems, of 5G radio frequency communication networks, of data centers, and of servers.

As an example, the MOSFET transistor may be incorporated in a device intended to be used in personal electronics, for example to increase a volume of information exchanged by radio frequency communication, in 5G communication systems, or more generally in any connected device. The device is, for example, a cell phone, or smartphone, or forms part of an Internet of Things network.

As an example, the MOSFET transistor may be incorporated in a device intended to be used in communications equipment, or in computers and peripherals. The device is used, for example, in 5G infrastructures and dedicated data centers.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A metal oxide field effect transistor (MOSFET) transistor comprising:
a semiconductor substrate extending along a plane;
a drain region and a source region located in an active area of the semiconductor substrate along a first direction of the plane; and
a gate structure comprising
a first region insulated from, and located at least partly above, the active area, and
a second region insulated from, and located above, the first region;
the first region having a first length in the first direction, the second region having a second length in the first direction greater than the first length, and the second region further extending on either side of the first region in the first direction;
along a second direction of the plane perpendicular to the first direction, the second region having a first longitudinal edge that reaches or extends beyond a second longitudinal edge of the first region; and
the second region having an opening that extends in the second direction from a third longitudinal edge of the second region opposite to the first longitudinal edge.

2. The MOSFET transistor according to claim 1, wherein the first region of the gate structure is positioned on a gate insulator layer and is overlaid by an inter-gate insulator layer, and the second region of the gate structure is positioned astride, at least in the first direction, the first region overlaid by the inter-gate insulator layer and the gate insulator layer.

3. The MOSFET transistor according to claim 1, wherein the active area has a third length in the first direction that is greater than the second length, and a third width in the second direction that is smaller than a first width of the first region in the second direction and smaller than a second width of the second region in the second direction.

4. The MOSFET transistor according to claim 1, wherein the opening of the second region is a notch that stops before the first longitudinal edge.

5. The MOSFET transistor according to claim 4, wherein the notch stops above the active area.

6. The MOSFET transistor according to claim 4, wherein the notch stops before the active area.

7. The MOSFET transistor according to claim 4, wherein the notch extends above the active area.

8. The MOSFET transistor according to claim 1, wherein the opening extends all the way to the first longitudinal edge, such that the second region is in two parts separated by the opening.

9. The MOSFET transistor according to claim 1, wherein the second region extends beyond the second longitudinal edge in the second direction, and the first region extends beyond the third longitudinal edge in the second direction.

10. The MOSFET transistor according to claim 1, wherein the second region further extends on either side of the first region in the second direction, a first width of the first region in the second direction being smaller than a second width of the second region in the second direction.

11. The MOSFET transistor according to claim 1, further comprising:
a first contact on the first region; and
at least one second contact on the second region.

12. The MOSFET transistor according to claim 11, wherein the first contact is positioned at least partially in the opening.

13. The MOSFET transistor of claim 11, wherein the opening extends all the way to the first longitudinal edge such that the second region is in two parts separated by the opening, and wherein the at least one second contact comprises two second contacts, each of the two parts having one of the two second contacts.

14. The MOSFET transistor according to claim 11, wherein the first contact, or the at least one shared contact, is positioned at least partially in the opening of the second region.

15. The MOSFET transistor according to claim 1, further comprising at least one shared contact astride the first region and the second region.

16. The MOSFET transistor of claim 15, wherein the opening extends all the way to the first longitudinal edge such that the second region is in two parts separated by the opening, and wherein the at least one shared contact comprises two shared contacts.

17. The MOSFET transistor according to claim 1, wherein:
the first region of the gate structure is between the drain region and the source region; and/or
the second region of the gate structure is between the drain region and the source region; and/or
the drain region and the source region are each comprised in a lightly-doped drain region located at least partially under the second region of the gate structure; and/or
the active area is surrounded by insulating trenches, the first and second regions also extending above the insulating trenches.

18. A method of manufacturing a MOSFET transistor, the method comprising:
forming a first region of a gate structure, the first region being insulated from and above an active area of a semiconductor substrate extending along a plane, the first region having a first length in a first direction of the plane;
forming a second region of the gate structure, the second region being insulated from and above the first region, the second region having a second length in the first direction greater than the first length, and the second region further extending on either side of the first region in the first direction, the second region being formed so that a first longitudinal edge of the second region reaches or extends beyond a second longitudinal edge of the first region along a second direction of the plane perpendicular to the first direction, and the forming of the second region comprising forming an opening in the second direction from a third longitudinal edge of the second region opposite to the first longitudinal edge; and
forming a drain region and a source region on either side of the second region in the first direction.

19. The method according to claim 18, further comprising, after the forming of the first region, and before the forming of the second region, forming lightly-doped drain regions on either side of the first region in the first direction.

20. The method according to claim 18, further comprising forming a first contact on the first region, wherein the first contact is positioned at least partially in the notch.

21. The method according to claim 18, wherein the second region extends beyond the second longitudinal edge of the first region in the second direction, wherein the first region extends beyond the third longitudinal edge of the second region in the second direction, and wherein a first width of the first region in the second direction is smaller than a second width of the second region in the second direction.

22. The method according to claim 18, wherein forming insulating trenches surrounding the active area, and wherein the second region extends over the insulating trenches in the second direction.

23. An electronic circuit comprising:
a semiconductor substrate extending along a plane; and
at least one MOSFET transistor comprising:
a drain region and a source region located in an active area of the semiconductor substrate along a first direction of the plane; and
a gate structure comprising
a first region insulated from, and located at least partly above, the active area, and
a second region insulated from, and located above, the first region;
the first region having a first length in the first direction, the second region having a second length in the first direction greater than the first length, and the second region further extending on either side of the first region in the first direction;
along a second direction of the plane perpendicular to the first direction, the second region having a first longitudinal edge that reaches or extends beyond a second longitudinal edge of the first region; and
the second region having an opening that extends in the second direction from a third longitudinal edge of the second region opposite to the first longitudinal edge.
